(19) United States
(12) Patent Application Publication
(10) Pub. No.: US 2025/0030972 A1
(43) Pub. Date: Jan. 23, 2025

(54) AMBIENT NOISE MANAGEMENT TO FACILITATE USER AWARENESS AND INTERACTION

(71) Applicant: BOSE CORPORATION, Framingham, MA (US)

(72) Inventors: Chuan-Che HUANG, Framingham, MA (US); Shuo ZHANG, Belmont, MA (US); Lauren WESTENDORF, Boston, MA (US); Jeremy KEMMERER, Holliston, MA (US)

(21) Appl. No.: 18/356,976

(22) Filed: Jul. 21, 2023

(51) Int. Cl. H04R 1/10; G10K 11/175; G10L 25/78

(52) U.S. Cl. CPC H04R 1/1083; G10K 11/175; G10L 25/78; H04R 2460/01

(57) ABSTRACT

Aspects of the present disclosure provide techniques, including devices and systems implementing the techniques, to manage ambient noise in a wearable audio output device to facilitate increased awareness for a user of the wearable audio output device. One example technique for managing ambient noise generally includes determining a first event, ducking an audio level of the wearable audio output device from a first level to a second level based on the determination, monitoring for a second event, and ducking the audio level of the wearable audio output device to a third level based on the monitoring, wherein the second level is different than the third level. Such techniques may help to more accurately determine the occurrence of events that are important to the user and manage the wearable audio output device to facilitate user awareness, as well as mitigate the undesirable consequences of events that are unimportant to the user.

### FIELD

Aspects of the disclosure generally relate to wearable devices, and, more particularly, to techniques to enable a wearable device to manage ambient noise.

### BACKGROUND

Wearable audio output devices may provide a user with a desired transmitted or reproduced audio experience by masking, proofing against, or canceling ambient noises. For example, high volume output or white noises generated by the wearable devices may mask ambient noises. Soundproofing in the wearable audio output devices may also reduce sound pressure by reflecting or absorbing sound energy. In addition, noise cancellation (e.g., active noise cancelling (ANC)), or active noise control/reduction, may reduce ambient noises by the addition of a second sound that cancels the ambient noises to provide an immersive audio experience to the user. In these cases, the user may be effectively isolated from ambient noise, and may not become aware of events occurring in the vicinity of the user. As a result, the user may be unaware of events that are important to the user.

Accordingly, methods for facilitating user awareness and interaction using wearable audio output devices, as well as apparatuses and systems configured to implement these methods, are desired.

### SUMMARY

All examples and features mentioned herein can be combined in any technically possible manner.

Aspects of the present disclosure provide a method for managing ambient noise in a wearable device. The method includes determining a first event; ducking an audio level of the wearable device from a first level to a second level based on the determination; monitoring for a second event; and ducking the audio level of the wearable device to a third level based on the monitoring, wherein the second level is different than the third level.

In aspects, ducking the audio level of the wearable device includes gradually ducking the audio level of the wearable device.

In aspects, ducking the audio level of the wearable device includes at least one of: decreasing an audio volume of the wearable device; decreasing a noise cancellation of the wearable device; increasing a transparency of the wearable device; pausing an audio output of the wearable device; or outputting a notification sound from the wearable device.

In aspects, at least one of the second level or the third level is based, at least in part, on a user input.

In aspects, the method further includes determining a first confidence level associated with the first event, where the second level is based, at least in part, on the first confidence level.

In aspects, a duration of the ducking the audio level of the wearable device from the first level to the second level is based, at least in part, on the first confidence level.

In aspects, the method further includes determining a second confidence level associated with the second event, wherein the third level is based, at least in part, on the second confidence level.

In aspects, the first confidence level is based, at least in part, on one or more of: a type of the first event; a user input; or a user profile.

In aspects, the first event and the second event each include at least one of: a user speech vocalization; a non-speech vocalization; an environmental sound; or a user action.

In aspects, determining the first event and monitoring for the second event each include: measuring a sound using one or more microphones on the wearable device; or detecting an action using one or more sensors on the wearable device.

In aspects, the method further includes determining that the first event is not continuing; and returning the audio level of the wearable device to the first level based on the determination that the first event is not continuing.

Aspects of the present disclosure provide a system. The system includes a wearable device including one or more microphones configured to measure ambient sound; and one or more processors coupled to the wearable device. The one or more processors are configured to: determine a first event; duck an audio level of the wearable device from a first level to a second level based on the determination; monitor for a second event; and duck the audio level of the wearable device to a third level based on the monitoring, wherein the second level is different than the third level.

In aspects, the one or more processors are configured to duck the audio level of the wearable device by gradually ducking the audio level of the wearable device.

In aspects, to duck the audio level of the wearable device, the one or more processors are configured to at least one of: decrease an audio volume of the wearable device; decrease a noise cancellation of the wearable device; increase a transparency of the wearable device; pause an audio output of the wearable device; or output a notification sound from the wearable device.

In aspects, the one or more processors are further configured to determine a first confidence level associated with the first event, wherein the second level is based, at least in part, on the first confidence level.

In aspects, the first confidence level is based, at least in part, on one or more of: a type of the first event; a user input; or a user profile.

Aspects of the present disclosure provide a non-transitory computer-readable medium including computer-executable instructions that, when executed by one or more processors of a wearable device, cause the wearable device to perform a method for managing ambient noise. The method includes determining a first event; ducking an audio level of the wearable device from a first level to a second level based on the determination; monitoring for a second event; and ducking the audio level of the wearable device to a third level based on the monitoring, wherein the second level is different than the third level. In aspects, ducking the audio level of the wearable device includes gradually ducking the audio level of the wearable device.

In aspects, ducking the audio level of the wearable device includes at least one of: decreasing an audio volume of the wearable device; decreasing a noise cancellation of the wearable device; increasing a transparency of the wearable device; pausing an audio output of the wearable device; or outputting a notification sound from the wearable device.

In aspects, the method further includes determining a first confidence level associated with the first event, wherein the second level is based, at least in part, on the first confidence level.

Two or more features described in this disclosure, including those described in this summary section, may be combined to form implementations not specifically described herein.

The details of one or more implementations are set forth in the accompanying drawings and the description below. Other features, objects, and advantages will be apparent from the description and drawings, and from the claims.

### BRIEF DESCRIPTION OF THE DRAWINGS

FIG. 1 illustrates an example system, in which aspects of the present disclosure may be implemented.

FIG. 2A illustrates an exemplary wireless audio device, in which aspects of the present disclosure may be implemented.

FIG. 2B illustrates an exemplary computing device, in which aspects of the present disclosure may be implemented.

FIG. 3 illustrates example operations performed by a wearable device worn by a user for managing ambient noise to facilitate user awareness and interaction, according to certain aspects of the present disclosure.

FIG. 4 is a state diagram illustrating example operations performed by a wearable device for managing ambient noise using multi-stage actions, according to certain aspects of the present disclosure.

FIG. 5 is a state diagram illustrating example operations performed by a wearable device for managing ambient noise using multi-stage and confidence-based actions, according to certain aspects of the present disclosure.

Like numerals indicate like elements.

### DETAILED DESCRIPTION

Certain aspects of the present disclosure provide techniques, including devices and system implementing the techniques, for providing ambient noise management in a wearable device to facilitate user awareness and interaction. The ambient noise management may involve using one or more of multi-stage ducking, gradual ducking, or confidence-based ducking to mitigate the impact of unimportant events on a user's audio experience while facilitating user awareness of important events, thus enabling the user to interact with the important events as desired.

Wearable audio output devices help users enjoy high quality audio and participate in productive voice calls. However, users often lose at least some situational awareness when using wearable audio output devices. In some cases, situational awareness is decreased when the volume of the audio is at an excessive level that masks over ambient sound, or the devices have good soundproofing (e.g., passive sound insulation). In addition, wearable audio output devices with noise cancellation also reduce situational awareness by attenuating sounds, including noise external to the audio output devices. Situational awareness may also be decreased when the user is in a focused state, such as when working, studying, or reading, with the aid of the wearable audio device (e.g., canceling or attenuating ambient sound). In other words, wearable audio output devices (especially those utilizing noise cancellation) tend to isolate the user from the surrounding world, making it difficult for the user to be aware of important events occurring around them, such as when someone is trying to talk to the user. In some cases, the user may want to quickly adjust the wearable device's audio level (e.g., by lowering noise cancellation and audio volume) to respond to an important event, such as another person speaking to them, and enable a conversation with that nearby person. However, it is often cumbersome for users to control or doff their earbuds or headphones to respond to the event.

One possible solution to manage the ambient noise and facilitate user awareness and interaction is to embed sound event detection algorithms in the wearable device, so that the user may turn off noise cancellation or pause audio content when an important event is detected (e.g., self-voice or a nearby sound event). However, it may be difficult for a wearable device to differentiate between different sounds with similar characteristics, such as differentiating between an event when someone is merely chatting nearby and when someone is attempting to talk to the user. Similarly, it may be difficult for a wearable device to determine if a sound event comes from nearby entertainment (e.g., television, music, a podcast, etc.), which may not be important to the user, or from someone talking to you (e.g., a family member), which may be important to the user. As a result of not being able to distinguish between when an event that is important to the user has been detected and when an event that is not important to the user has been detected, the wearable device may not take appropriate actions in response to the detected event. For example, the wearable device may greatly decrease the audio volume of the wearable device output, or even pause the audio output in response to a detected event that is not important to the user (e.g., co-workers conversing with each other), greatly disrupting the user's audio experience. In another example, the wearable device may output a notification sound (e.g., a tone) in response to a detected event that is not important to the user, which may also disrupt the user's audio experience. The present disclosure may enable the wearable device of a user to minimize the undesirable consequences of detecting an event and negatively impacting the user's audio experience when an unimportant event is detected, while enabling the wearable device to take appropriate and sufficient action to allow the user to be aware of important events. As a result, the user may be able to continue to enjoy their audio experience with minimal interruption when unimportant events are detected, and be alerted or otherwise made aware of important events as desired.

### An Example System

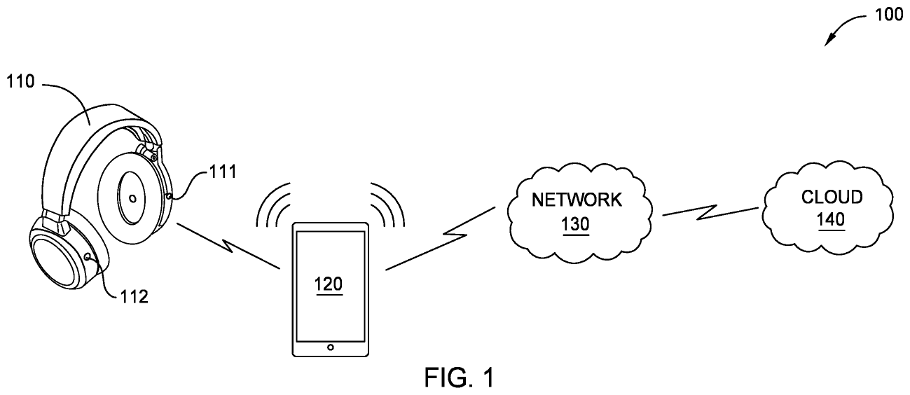

FIG. 1 illustrates an example system 100, in which aspects of the present disclosure are practiced. As shown, system 100 includes a wearable device 110 communicatively coupled with a computing device 120. The wearable device 110 may be configured to be worn by a user, and may be a headset that includes two or more speakers and two or more microphones, as illustrated in FIG. 1. The computing device 120 is illustrated as a smartphone or a tablet computer wirelessly paired with the wearable device 110. At a high level, the wearable device 110 may play audio content transmitted from the computing device 120. The user may use the graphical user interface (GUI) on the computing device 120 to select the audio content and/or adjust settings of the wearable device 110. The wearable device 110 provides soundproofing, active noise cancellation, and/or other audio enhancement features to play the audio content transmitted from the computing device 120. According to aspects of the present disclosure, upon the determining of an event (e.g., measuring a sound and/or detecting an action), the wearable device 110 and/or the computing device 120 may facilitate the awareness of the user by taking one or more actions. The one or more actions may include, for example, decreasing an audio volume of the wearable device 110, decreasing a noise cancellation of the wearable device 110, increasing a transparency of the wearable device 110, pausing an audio output of the wearable device 110, or outputting a notification sound from the wearable device 110.

In certain aspects, the wearable device 110 includes at least two microphones 111 and 112 to capture ambient sound. The captured sound may be used for active noise cancellation and/or event detection. For example, the microphones 111 and 112 may be positioned on opposite sides of the wearable device 110, as illustrated.

In certain aspects, the wearable device 110 includes voice activity detection (VAD) circuitry capable of detecting the presence of speech signals (e.g., human speech signals) in a sound signal received by the microphones 111, 112 of the wearable device 110. For instance, the microphones 111, 112 of the wearable device 110 can receive ambient and external sounds in the vicinity of the wearable device 110, including speech uttered by the user. The sound signal received by the microphones 111, 112 may have the speech signal mixed in with other sounds in the vicinity of the wearable device 110. Using the VAD, the wearable device 110 may detect and extract the speech signal from the received sound signal. In certain aspects, the VAD circuitry may be used to detect and extract speech uttered by the user in order to facilitate a voice call, voice chat between the user and another person, or voice commands for a virtual personal assistant (VPA), such as a cloud based VPA. In some cases, detections or triggers can include self-VAD (only starting up when the user is speaking, regardless of whether others in the area are speaking), active transport (sounds captured from transportation systems), head gestures, buttons, computing device based triggers (e.g., pause/un-pause from the phone), changes with input audio level, and/or audible changes in environment, among others. The voice activity detection circuitry may run or assist running the activity detection algorithm disclosed herein.

In certain aspects, the wearable device 110 includes speaker identification circuitry capable of detecting an identity of a speaker to which a detected speech signal relates to. For example, the speaker identification circuitry may analyze one or more characteristics of a speech signal detected by the VAD circuitry and determine that the user of the wearable device 110 is the speaker. In certain aspects, the speaker identification circuitry may use any of the existing speaker recognition methods and related systems to perform the speaker recognition.

The wearable device 110 further includes hardware and circuitry including processor(s)/processing system and memory configured to implement one or more sound management capabilities or other capabilities including, but not limited to, noise canceling circuitry (not shown) and/or noise masking circuitry (not shown), body movement detecting devices/sensors and circuitry (e.g., one or more accelerometers, one or more gyroscopes, one or more magnetometers, etc.), geolocation circuitry and other sound processing circuitry. The noise cancelling circuitry is configured to reduce unwanted ambient sounds external to the wearable device 110 by using active noise cancelling (also known as active noise reduction). The sound masking circuitry is configured to reduce distractions by playing masking sounds via the speakers of the wearable device 110. The movement detecting circuitry is configured to use devices/sensors such as an accelerometer, gyroscope, magnetometer, or the like to detect whether the user wearing the wearable device 110 is moving (e.g., walking, running, in a moving mode of transport, etc.) or is at rest and/or the direction the user is looking or facing. The movement detecting circuitry may also be configured to detect a head position of the user for use in determining an event, as will be described herein, as well as in augmented reality (AR) applications where an AR sound is played back based on a direction of gaze of the user.

In an aspect, the wearable device 110 is wirelessly connected to the computing device 120 using one or more wireless communication methods including, but not limited to, Bluetooth, Wi-Fi, Bluetooth Low Energy (BLE), other radio frequency (RF) based techniques, or the like. In certain aspects, the wearable device 110 includes a transceiver that transmits and receives data via one or more antennae in order to exchange audio data and other information with the computing device 120.

In an aspect, the wearable device 110 includes communication circuitry capable of transmitting and receiving audio data and other information from the computing device 120. The wearable device 110 also includes an incoming audio buffer, such as a render buffer, that buffers at least a portion of an incoming audio signal (e.g., audio packets) in order to allow time for retransmissions of any missed or dropped data packets from the computing device 120. For example, when the wearable device 110 receives Bluetooth transmissions from the computing device 120, the communication circuitry typically buffers at least a portion of the incoming audio data in the render buffer before the audio is actually rendered and output as audio to at least one of the transducers (e.g., audio speakers) of the wearable device 110. This is done to ensure that even if there are RF collisions that cause audio packets to be lost during transmission, there is time for the lost audio packets to be retransmitted by the computing device 120 before the lost audio packets have been rendered by the wearable device 110 for output by one or more acoustic transducers of the wearable device 110.

The wearable device 110 is illustrated as over-the-head headphones; however, the techniques described herein apply to other wearable devices, such as wearable audio devices, including any audio output device that fits around, on, in, or near an car (including open-car audio devices worn on the head or shoulders of a user) or other body parts of a user, such as head or neck. The wearable device 110 may take any form, wearable or otherwise, including standalone devices (including automobile speaker system), stationary devices (including portable devices, such as battery powered portable speakers), headphones (including over-ear headphones, on-car headphones, in-ear headphones), earphones, earpieces, headsets (including virtual reality (VR) headsets and AR headsets), goggles, headbands, earbuds, armbands, sport headphones, neckbands, or eyeglasses.

In certain aspects, the wearable device 110 is connected to the computing device 120 using a wired connection, with or without a corresponding wireless connection. The computing device 120 may be a smartphone, a tablet computer, a laptop computer, a digital camera, or other computing device that connects with the wearable device 110. As shown, the computing device 120 can be connected to a network 130 (e.g., the Internet) and may access one or more services over the network. As shown, these services can include one or more cloud services 140.

In certain aspects, the computing device 120 can access a cloud server in the cloud 140 over the network 130 using a mobile web browser or a local software application or “app” executed on the computing device 120. In certain aspects, the software application or “app” is a local application that is installed and runs locally on the computing device 120. In certain aspects, a cloud server accessible on the cloud 140 includes one or more cloud applications that are run on the cloud server. The cloud application may be accessed and run by the computing device 120. For example, the cloud application can generate web pages that are rendered by the mobile web browser on the computing device 120. In certain aspects, a mobile software application installed on the computing device 120 or a cloud application installed on a cloud server, individually or in combination, may be used to implement the techniques for low latency Bluetooth communication between the computing device 120 and the wearable device 110 in accordance with aspects of the present disclosure. In certain aspects, examples of the local software application and the cloud application include a gaming application, an audio AR or VR application, and/or a gaming application with audio AR or VR capabilities. The computing device 120 may receive signals (e.g., data and controls) from the wearable device 110 and send signals to the wearable device 110.

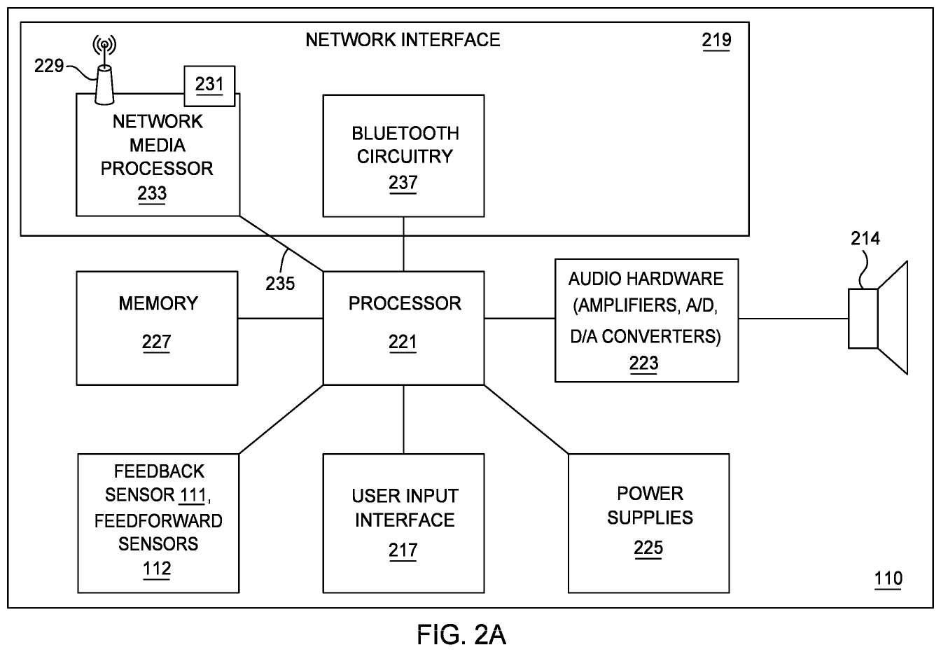

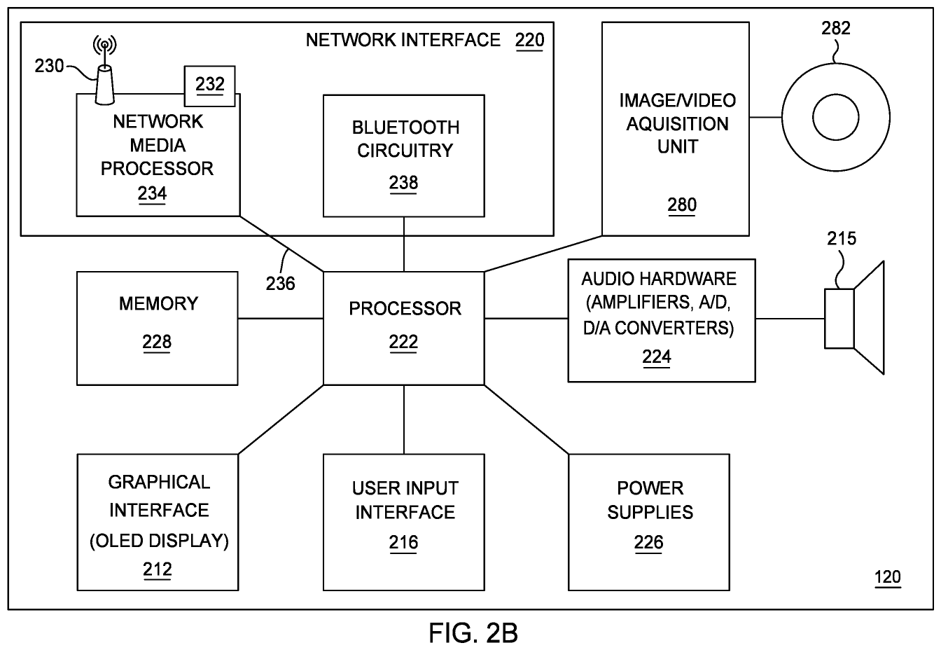

FIG. 2A illustrates an exemplary wearable device 110 and some of its components. Other components may be inherent in the wearable device 110 and not shown in FIG. 2A. For example, the wearable device 110 may include an enclosure that houses an optional graphical interface (e.g., an OLED display) which can provide the user with information regarding currently playing (“Now Playing”) music.

The wearable device 110 includes one or more electro-acoustic transducers (or speakers) 214 for outputting audio. The wearable device 110 also includes a user input interface 217. The user input interface 217 may include a plurality of preset indicators, which may be hardware buttons. The preset indicators may provide the user with easy, one press access to entities assigned to those buttons. The assigned entities may be associated with different ones of the digital audio sources such that a single wearable device 110 may provide for single press access to various different digital audio sources.

The wearable device 110 may include a feedback sensor 111 and feedforward sensors 112. The feedback sensor 111 and feedforward sensors 112 may include two or more microphones (e.g., microphones 111, 112 as illustrated in FIG. 1) for capturing ambient sound and provide audio signals for determining location attributes of events. For example, the feedback sensor 111 may provide a mechanism for determining transmission delays between the computing device 120 and the wearable device 110. The transmission delays may be used to reduce errors in subsequent computation. The feedback sensor 111 may provide two or more channels of audio signals. The audio signals are captured by microphones that are spaced apart and may have different directional responses. The two or more channels of audio signals may be used for calculating directional attributes of an event of interest.

As shown in FIG. 2A, the wearable device 110 includes an acoustic driver or speaker 214 to transduce audio signals to acoustic energy through audio hardware 223. The wearable device 110 also includes a network interface 219, at least one processor 221, the audio hardware 223, power supplies 225 for powering the various components of the wearable device 110, and memory 227. In certain aspects, the processor 221, the network interface 219, the audio hardware 223, the power supplies 225, and the memory 227 are interconnected using various buses 235, and several of the components can be mounted on a common motherboard or in other manners as appropriate.

The network interface 219 provides for communication between the wearable device 110 and other electronic computing devices via one or more communications protocols. The network interface 219 provides either or both of a wireless network interface 229 and a wired interface 231. The wireless interface 229 allows the wearable device 110 to communicate wirelessly with other devices in accordance with a wireless communication protocol such as IEEE 802.11. The wired interface 231 provides network interface functions via a wired (e.g., Ethernet) connection for reliability and fast transfer rate, for example, used when the wearable device 110 is not worn by a user. Although illustrated, the wired interface 231 is optional.

In certain aspects, the network interface 219 includes a network media processor 233 for supporting Apple AirPlay® and/or Apple Airplay® 2. For example, if a user connects an AirPlay® or Apple Airplay® 2 enabled device, such as an iPhone or iPad device, to the network, the user can then stream music to the network connected audio playback devices via Apple AirPlay® or Apple Airplay® 2. Notably, the audio playback device can support audio-streaming via AirPlay®, Apple Airplay® 2 and/or Digital Living Network Alliance's (DLNA) Universal Plug and Play (UPnP) protocols, all integrated within one device.

All other digital audio received as part of network packets may pass straight from the network media processor 233 through a USB bridge (not shown) to the processor 221 and runs into the decoders, DSP, and eventually is played back (rendered) via the electro-acoustic transducer(s) 214.

The network interface 219 can further include Bluetooth circuitry 237 for Bluetooth applications (e.g., for wireless communication with a Bluetooth enabled audio source such as a smartphone or tablet) or other Bluetooth enabled speaker packages. In some aspects, the Bluetooth circuitry 237 may be the primary network interface 219 due to energy constraints. For example, the network interface 219 may use the Bluetooth circuitry 237 solely for mobile applications when the wearable device 110 adopts any wearable form. For example, BLE technologies may be used in the wearable device 110 to extend battery life, reduce package weight, and provide high quality performance without other backup or alternative network interfaces.

In certain aspects, the network interface 219 supports communication with other devices using multiple communication protocols simultaneously at one time. For instance, the wearable device 110 can support Wi-Fi/Bluetooth coexistence and can support simultaneous communication using both Wi-Fi and Bluetooth protocols at one time. For example, the wearable device 110 can receive an audio stream from a smart phone using Bluetooth and can further simultaneously redistribute the audio stream to one or more other devices over Wi-Fi. In certain aspects, the network interface 219 may include only one RF chain capable of communicating using only one communication method (e.g., Wi-Fi or Bluetooth) at one time. In this context, the network interface 219 may simultaneously support Wi-Fi and Bluetooth communications by time sharing the single RF chain between Wi-Fi and Bluetooth, for example, according to a time division multiplexing (TDM) pattern.

Streamed data may pass from the network interface 219 to the processor 221. The processor 221 may execute instructions (e.g., for performing, among other things, digital signal processing, decoding, and equalization functions), including instructions stored in the memory 227. The processor 221 may be implemented as a chipset of chips that includes separate and multiple analog and digital processors. The processor 221 may provide, for example, for coordination of other components of the audio wearable device 110, such as control of user interfaces.

In certain aspects, the protocols stored in the memory 227 may include BLE according to, for example, the Bluetooth Core Specification Version 5.2 (BT5.2). The wearable device 110 and the various components therein are provided herein to sufficiently comply with or perform aspects of the protocols and the associated specifications. For example, BT5.2 includes enhanced attribute protocol (EATT) that supports concurrent transactions. A new L2CAP mode is defined to support EATT. As such, the wearable device 110 includes hardware and software components sufficiently to support the specifications and modes of operations of BT5.2, even if not expressly illustrated or discussed in this disclosure. For example, the wearable device 110 may utilize LE Isochronous Channels specified in BT5.2.

The processor 221 provides a processed digital audio signal to the audio hardware 223 which includes one or more digital-to-analog (D/A) converters for converting the digital audio signal to an analog audio signal. The audio hardware 223 also includes one or more amplifiers which provide amplified analog audio signals to the electro-acoustic transducer(s) 214 for sound output. In addition, the audio hardware 223 may include circuitry for processing analog input signals to provide digital audio signals for sharing with other devices, for example, other speaker packages for synchronized output of the digital audio.

The memory 227 can include, for example, flash memory and/or non-volatile random access memory (NVRAM). In some aspects, instructions (e.g., software) are stored in an information carrier. The instructions, when executed by one or more processing devices (e.g., the processor 221), perform one or more processes, such as those described elsewhere herein. The instructions can also be stored by one or more storage devices, such as one or more computer or machine-readable mediums (for example, the memory 227, or memory on the processor). The instructions can include instructions for performing decoding (i.e., the software modules include the audio codecs for decoding the digital audio streams), as well as digital signal processing and equalization. In certain aspects, the memory 227 and the processor 221 may collaborate in data acquisition and real time processing with the feedback microphone 111 and feedforward microphones 112.

FIG. 2B illustrates an exemplary computing device 120, such as a smartphone or a mobile computing device, in accordance with certain aspects of the present disclosure. Some components of the computing device 120 may be inherent and not shown in FIG. 2B. For example, the computing device 120 may include an enclosure. The enclosure may house an optional graphical interface 212 (e.g., an organic light-emitting diode (OLED) display), as shown. The graphical interface 212 provides the user with information regarding currently playing (“Now Playing”) music or video. The computing device 120 includes one or more electro-acoustic transducers 215 for outputting audio. The computing device 120 may also include a user input interface 216 that enables user input.

The computing device 120 also includes a network interface 220, at least one processor 222, audio hardware 224, power supplies 226 for powering the various components of the computing device 120, and a memory 228. In certain aspects, the processor 222, the graphical interface 212, the network interface 220, the audio hardware 224, the one or more power supplies 226, and the memory 228 are interconnected using various buses 236, and several of the components can be mounted on a common motherboard or in other manners as appropriate. In some aspects, the processor 222 of the computing device 120 is more powerful in terms of computation capacity than the processor 221 of the wearable device 110. Such difference may be due to constraints of weight, power supplies, and other requirements. Similarly, the power supplies 226 of the computing device 120 may be of a greater capacity and heavier than the power supplies 225 of the wearable device 110.

The network interface 220 provides for communication between the computing device 120 and the wearable device 110, as well as other audio sources and other wireless speaker packages including one or more networked wireless speaker packages and other audio playback devices via one or more communications protocols. The network interface 220 can provide either or both of a wireless interface 230 and a wired interface 232. The wireless interface 230 allows the computing device 120 to communicate wirelessly with other devices in accordance with a wireless communication protocol, such as IEEE 802.11. The wired interface 232 provides network interface functions via a wired (e.g., Ethernet) connection.

In certain aspects, the network interface 220 may also include a network media processor 234 and Bluetooth circuity 238, similar to the network media processor 233 and Bluetooth circuity 237 in the wearable device 110 in FIG. 2A. Further, in aspects, the network interface 220 supports communication with other devices using multiple communication protocols simultaneously at one time, as described with respect to the network interface 219 in FIG. 2A.

All other digital audio received as part of network packets comes straight from the network media processor 234 through a bus 236 (e.g., universal serial bus (USB) bridge) to the processor 222 and runs into the decoders, DSP, and eventually is played back (rendered) via the electro-acoustic transducer(s) 215.

The computing device 120 may also include an image or video acquisition unit 280 for capturing image or video data. For example, the image or video acquisition unit 280 may be connected to one or more cameras 282 and capable of capturing still or motion images. The image or video acquisition unit 280 may operate at various resolutions or frame rates according to a user selection. For example, the image or video acquisition unit 280 may capture 4K videos (e.g., a resolution of 3840 by 2160 pixels) with the one or more cameras 282 at 30 frames per second, FHD videos (e.g., a resolution of 1920 by 1080 pixels) at 60 frames per second, or a slow motion video at a lower resolution, depending on hardware capabilities of the one or more cameras 282 and the user input. The one or more cameras 282 may include two or more individual camera units having respective lenses of different properties, such as focal length resulting in different fields of views. The image or video acquisition unit 280 may switch between the two or more individual camera units of the cameras 282 during a continuous recording.

Captured audio or audio recordings, such as the voice recording captured at the wearable device 110, may pass from the network interface 220 to the processor 222. The processor 222 executes instructions within the wireless speaker package (e.g., for performing, among other things, digital signal processing, decoding, and equalization functions), including instructions stored in the memory 228. The processor 222 can be implemented as a chipset of chips that includes separate and multiple analog and digital processors. The processor 222 can provide, for example, for coordination of other components of the audio computing device 120, such as control of user interfaces and applications. The processor 222 provides a processed digital audio signal to the audio hardware 224 similar to the respective operation by the processor 221 described in FIG. 2A.

The memory 228 can include, for example, flash memory and/or non-volatile random access memory (NVRAM). In certain aspects, instructions (e.g., software) are stored in an information carrier. The instructions, when executed by one or more processing devices (e.g., the processor 222), perform one or more processes, such as those described herein. The instructions can also be stored by one or more storage devices, such as one or more computer or machine-readable mediums (for example, the memory 228, or memory on the processor 222). The instructions can include instructions for performing decoding (i.e., the software modules include the audio codecs for decoding the digital audio streams), as well as digital signal processing and equalization.

### Example Operations for Ambient Noise Management

Aspects of the present disclosure provide techniques, including devices and system implementing the techniques, for providing ambient noise management in a wearable device to facilitate user awareness and interaction. The present disclosure may enable the user's wearable device to minimize the undesirable consequences of detecting an event and negatively impacting the user's audio experience when the event is unimportant, while enabling the wearable device to take appropriate action to allow the user to respond when the event is important.

In certain aspects, a wearable device may use multi-stage ducking (e.g., multiple stages of audio level adjustment) to manage ambient noise. In some cases, the ambient sound detected may be a voice event. In these cases, the wearable device may determine when the voice event is the voice of a nearby person (e.g., far-field voice), or when the voice belongs to the user (e.g., self-voice). For example, when the wearable device determines that a nearby person is talking to a user using the wearable device employing noise isolation techniques, the wearable device may duck the audio level (e.g., ramp down the audio volume mildly and adjust noise cancellation), to enable the user to be aware of their environment, so that the user may determine if they want to engage in a conversation. When the user decides to engage with the voice event, and begins speaking, the wearable device may duck the audio level again (e.g., ramp down the audio volume more deeply and further adjust noise cancellation), to enable the user to more fully hear themselves and the nearby voice, to permit the user and nearby person to have a smooth conversation. The wearable device may further determine when the conversation has ended (e.g., detect whether there is any more talking happening) using both self-voice and far-field voice detection, and may automatically return the audio level to the previous audio level (e.g., the audio volume and noise cancellation setting before the device ducked the audio level). This multi-stage ducking approach may help mitigate the determination of false positives, such as when people are talking near the user, but are not talking directly at or with the user. Because the wearable device may only slightly duck the audio level (e.g., mildly decreasing the audio volume level and slightly reducing noise cancellation), the interruption resulting from events that may not be of interest to the user (e.g., unimportant events) is less intrusive. However, the slight duck in the audio level may be sufficient to increase the awareness of the user enough so that the user may be aware of important events, and able to respond.

In some cases, the wearable device may detect a voice event, and determine that the voice event detected by the wearable device is the voice of the user (e.g., self-voice). In these cases, the wearable device may duck the audio level (e.g., ramp down the audio volume mildly and adjust noise cancellation) to enable the user to be aware of their environment, so that the user may determine if nearby people are responding to the user, as well as to enhance the user's awareness of their environment generally. When the wearable device determines a nearby person is talking (e.g., far-field voice) in response to the user with the wearable device employing noise isolation techniques, the wearable device may duck the audio level again (e.g., ramp down the audio volume more deeply and further adjust noise cancellation), to enable the user to more fully hear themselves and the nearby voice, to permit the user and nearby person to have a smooth conversation. The wearable device may further determine when the conversation has ended (e.g., detect whether there is any more talking happening) using both self-voice and far-field voice detection, and may automatically return the audio level to the previous audio level (e.g., the audio volume and noise cancellation setting before the device ducked the audio level), as described above.

To help differentiate between the voice of one or more nearby people in a user's environment (e.g., far-field voice) and the voice of the user (e.g., self-voice), multiple different sensors may be used. For instance, one or more environment-facing microphones may be used in combination with one or more microphones facing and/or acoustically coupled with the user's ear canal(s) to help with the differentiation. Note that the one or more environment-facing microphones may also be used for active noise cancelling (ANC) purposes (generally known as feedforward microphones) and the one or more microphones facing and/or acoustically coupled with the user's ear canal(s) may also be used for ANC purposes. At least one accelerometer, at least one gyroscope, and/or at least one inertial measurement unit (IMU) could alternatively or additionally be used with the microphone(s) to help with the differentiation.

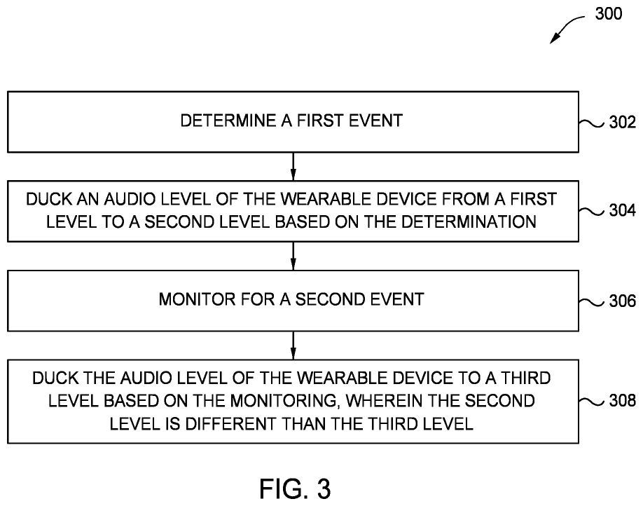

FIG. 3 illustrates example operations 300 performed by a wearable device (e.g., the wearable device 110 of FIGS. 1-2B) worn by a user for managing ambient noise, according to certain aspects of the present disclosure.

The operations may generally include, at block 302, determining a first event. In certain aspects, determining the first event may involve at least one of measuring a sound using one or more microphones (e.g., microphones 111, 112) on the wearable device, or detecting an action using one or more sensors (e.g., movement detecting circuitry) on the wearable device. The first event may involve at least one of a user speech (e.g., self-voice) measured by the one or more microphones, a non-speech vocalization (e.g., sneezing, crying, laughing) measured by the one or more microphones, an environmental sound (e.g., other ambient noises and/or nearby voice) measured by the one or more microphones, or a user action (e.g., user turning their head or reacting in some manner to the event) detected by the one or more sensors.

According to certain aspects, the operations 300 may further include, at block 304, ducking an audio level of the wearable device from a first level to a second level based on the determination. The first audio level may include one or more of an audio volume level, a noise cancellation level, a transparency level, or any other level associated with the audio output of the wearable device, and may be configurable by the user through the user input interface (e.g., user input interface 216, 217). In certain aspects, the first audio level may be different than the second audio level. For example, the second audio level may include one or more of a decreased audio level, decreased noise cancellation, or increased audio transparency, when compared to the first audio level.

Ducking the ducking the audio level of the wearable device may include at least one of decreasing an audio volume of the wearable device, decreasing a noise cancellation of the wearable device, increasing a transparency of the wearable device, pausing an audio output of the wearable device, or outputting a notification sound from the wearable device. For example, when the wearable device measures a nearby voice (e.g., determining the occurrence of a first event), the wearable device may decrease the audio volume (e.g., to 32 decibels (dB)) and noise cancellation of the wearable device, to facilitate user awareness and interaction.

As stated above, ducking the audio level may include pausing the audio output of the wearable device or outputting a notification sound. However, this may permit events that are unimportant to the user (e.g., when a user sneezes) to severely impact the audio experience of the user. In certain aspects, the wearable device may be configured to utilize gradual ducking to manage ambient noise. Gradual ducking involves gradually reducing the audio level (e.g., gradually reducing the audio volume or noise cancellation, as well as gradually increasing the transparency) to a user customizable level when an event is detected (e.g., self-voice, nearby voice, other ambient noise, like an appliance sound), and then gradually increase the audio level back to previous levels after the wearable device has determined that the event has ended. In certain aspects, ducking the audio level may instead involve a sudden or abrupt change in audio level.

According to certain aspects, the operations 300 may further include, at block 306, monitoring for a second event. Monitoring for the second event may be similar to determining the first event, as described above with respect to block 302, and may involve at least one of measuring a sound using one or more microphones (e.g., microphones 111, 112) on the wearable device (e.g., wearable device 110), or detecting an action using one or more sensors (e.g., movement detecting circuitry) on the wearable device. The second event may involve at least one of a user speech, a non-speech vocalization, an environmental sound, or a user action, as described above with respect to block 302.

According to certain aspects, the operations 300 may further include, at block 308, ducking the audio level of the wearable device to a third level based on the monitoring. The second audio level may be different than the third audio level, and both may be configurable by the user through the user input interface (e.g., user input interface 216, 217), or be baseline audio levels set by the wearable device. For example, the second audio level may include at least one of a decreased audio level, decreased noise cancellation, or increased audio transparency when compared to the third audio level.

The wearable device may duck the audio level a second time in response to the monitoring of the second event. Ducking the audio level of the wearable device a second time may include at least one of decreasing an audio volume of the wearable device, decreasing a noise cancellation of the wearable device, increasing a transparency of the wearable device, pausing an audio output of the wearable device, or outputting a notification sound from the wearable device. as described above. For example, when the wearable device measures a user speech vocalization (e.g., self-voice), the wearable device may further decrease the audio volume and noise cancellation of the wearable device (in light of the first duck of the audio level), and may also increase the transparency of the wearable device. In some cases, ducking the audio level of the wearable device may even involve pausing the audio output. In certain aspects, ducking the audio level of the wearable device to the third level may utilize gradual ducking, or abrupt ducking, as described above.

According to certain aspects, the operations 300 may further include determining that the first event is not continuing. Determining that the first event is not continuing may be similar to determining a first event and monitoring for a second event, as described above with respect to block 302 and block 306, and may involve at least one of measuring a sound using one or more microphones on the wearable device, or detecting an action using one or more sensors on the wearable device. In certain aspects, determining that the first event is not continuing may be performed after block 308.

According to certain aspects, the operations 300 may further include returning the audio level of the wearable device to the first level based on the determination that the first event is not continuing. For example, the wearable device may determine that there is no further ambient sound (e.g., further user speech or environmental sounds), and thus that the important event (e.g., the first event and subsequent second event) has ended. As a result, the wearable device may return the audio level to the first level (e.g., the previous audio level before the occurrence of the first event). In certain aspects, returning the audio level of the wearable device to the first level may utilize gradual ducking, or abrupt ducking, as described above.

According to certain aspects, the operations 300 may further include determining a confidence level associated with the first event. In certain aspects, the second audio level may based, at least in part, on the confidence level associated with the first event. In certain aspects, determining a confidence level associated with the first event may be performed after block 302. Determining a confidence level involves the wearable device making a determination of how confident the device is that the determined first event is an important event to the user.

In certain aspects, the confidence level may be based, at least in part, on an adjustable baseline confidence level that is preset on the wearable device. The confidence level determined by the wearable device may also be based (e.g., adjusted), at least in part, on one or more of the type of event that has been detected (e.g., self-voice, nearby voices, other ambient sounds), user programming (e.g., a user may explicitly program a confidence level associated with an event), or a user profile (e.g., the wearable device may implicitly create a user profile based on past user activity and using artificial intelligence/machine learning). The determined confidence level may help ensure that the actions taken by the device (e.g., ducking the audio level to the second level) match the determined confidence level by setting or adjusting the second audio level. In other words, the wearable device may set the second audio level to be more or less different than the first audio level depending on the confidence level that the event is important. For example, when the wearable device is very confident that the determined first event is important to the user, the device may take drastic action to facilitate user awareness and interaction. In this case, the wearable device may set the second audio level such that ducking from the first audio level to the second audio level greatly decreases the user's isolation as a result of the audio output of the wearable device (e.g., by greatly decreasing the audio volume, ending noise cancellation, greatly increasing transparency, or even pausing the audio output). In another example, when the wearable device is not confident that the determined first event is important to the user, the device may take only minimal action to facilitate user awareness and interaction. In this case, the wearable device may set the second audio level such that ducking from the first audio level to the second audio level only slightly decreases the user's isolation as a result of the audio output of the wearable device (e.g., by slightly decreasing the audio volume, slightly increasing transparency).

In certain aspects, the event type may be classified as user speech (e.g., self-voice), non-speech vocalization (e.g., sneezing, crying, laughing), an environmental sound (e.g., ambient noises and/or nearby voice), or a user action (e.g., user turning their head or reacting in some manner to the event). Different event types may impact what confidence level is determined by the wearable device. For example, if the wearable device detects a non-speech vocalization, the device may determine a low confidence level associated with the detected event (e.g., have a low confidence that the event is important to the user), and the device may adjust the second audio level so that it is only slightly different than the first audio level. As a result, the wearable device may take only limited action (e.g., ducking the audio level mildly from a first level to a second level) to minimize the impact on the user audio experience when the event is unimportant. However, if the wearable device detects a user speech vocalization, the device may determine a high confidence level associated with the detected event, and the device may adjust the second audio level so that it very different than the first audio level. As a result, ducking the audio level of the wearable device from the first level to the second level may involve more aggressive actions (e.g., pausing the audio, outputting a notification sound, ducking the audio volume more deeply, decreasing noise cancellation, increasing transparency) to facilitate interaction between the user and the event.

As described above, the confidence level determined by the wearable device may be based, at least in part, on user programming. In some cases, the user may program events that are important to the user into the wearable device. For example, the user may record a doorbell sound into the wearable device or the computing device (e.g., computing device 120) and designate the doorbell sound as an important event. In this case, when the wearable device determines that the doorbell sound has been detected in future situations, the device may determine a high confidence level associated with the event, and thus take aggressive actions to facilitate interaction between the user and the event, as described above. In another example, the user may record the user's voice, or another person's voice into the wearable device or the computing device and designate the voices as important events. In this case, when the wearable device determines that the user's programmed voice or another person's programmed voice have been detected in future situations, the device may determine a high confidence level associated with the event, and take aggressive actions to facilitate interaction between the user and the event, as described above.

In certain aspects, the wearable device (e.g., a wearable device with few-shot learning for sound event detection) may be configured to differentiate similar sounds with different characteristics, such as voice events from a television and from a user's spouse. In such a case, even if a detected event results from nearby voice, the wearable device may duck slightly more (e.g., by adjusting the second audio level to be more unlike the first audio level) when the voice event sounds more like the voice of the user's spouse, and duck less (e.g., by adjusting the second audio level such that it is similar to the first audio level) when the voice event does not. In some aspects, sensory information, such as user head movement, may also be used to determine and/or adjust the confidence level. For example, the wearable device may duck to a second level when a nearby voice is detected (as a result of low confidence), duck to a third level when the user turns their head to look at where the sound comes from (as a result of a higher confidence level), and then duck to a fourth level if the user starts speaking (as a result of a an even higher confidence level).

As described above, the confidence level determined by the wearable device may be based, at least in part, on a user profile. In some cases, the wearable device may utilize an algorithm to inform the determination of the confidence level associated with the first event. The confidence level determination algorithm may use deep learning to recognize the importance of various events to the user, and may form a pattern associated with the user's responses to certain events. Deep learning, or machine learning in more general situations, may use artificial neural networks with representation/feature learning performed by artificial intelligence. For example, if a user consistently/habitually responds to certain types of events, to certain user speech vocalization, to certain non-speech vocalization, to certain environmental sound, or if a user performs certain user action, the wearable device may infer or determine that these events are typically important, and thus may determine a high confidence level associated with these events. As a result of the high determined confidence level, the wearable device may take aggressive actions to facilitate interaction between the user and these events, as described above.

In certain aspects, the wearable device may determine a confidence level associated with the monitored second event, in accordance with aspects described herein. Determining the confidence level associated with the second event may be similar to determining the confidence level associated with the first event, as described above. The confidence level associated with the monitored second event may be an updated version of the confidence level associated with the determined first event, based, at least in part, on one or more of the type of second event that has been detected, the user programming, or the user profile. The determined confidence level associated with the second event may help ensure that the actions taken by the device (e.g., ducking the audio level to the third level) match the determined confidence level by setting or adjusting the third audio level, in a similar way to the confidence level associated with the first event described above.

In certain aspects, the confidence level associated with the second event determined by the wearable device may be based, at least in part, on one or more of the type of event that has been detected (e.g., self-voice, nearby voices, other ambient sounds), user programming (e.g., a user may program a confidence level associated with an event), or a user profile (e.g., based on past user activity and using artificial intelligence/machine learning), in a similar way to the confidence level associated with the first event. For example, when the first event is an environmental sound (e.g., nearby voices from colleagues), and the second event was a user action (e.g., a user moving their head), then the confidence level associated with the second event may be higher than the confidence level associated with the first event, as a result of the increased confidence that the first event and second event constitute an important event.

The ducking of the audio level of the wearable device from the first level to the second level may have a duration. The ducking of the audio level of the wearable device from the second level to the third level may also have a duration. The duration of each ducking of the audio level may be based, at least in part, on one or more of a type of the first event (e.g., self-voice, nearby voices, other ambient sounds), a user input (e.g., a user may explicitly program a confidence level associated with an event), a user profile (e.g., the wearable device may implicitly create a user profile based on past user activity and using artificial intelligence/machine learning), or a confidence level (e.g., a confidence level associated with the first event or a confidence level associated with the second event). For example, the duration of the ducking of the audio level of the wearable device from the first level to the second level may be based, at least in part, on the determined confidence level associated with the first event. The duration of the ducking of the audio level of the wearable device from the second level to the third level may be based, at least in part, on the determined confidence level associated with the second event.

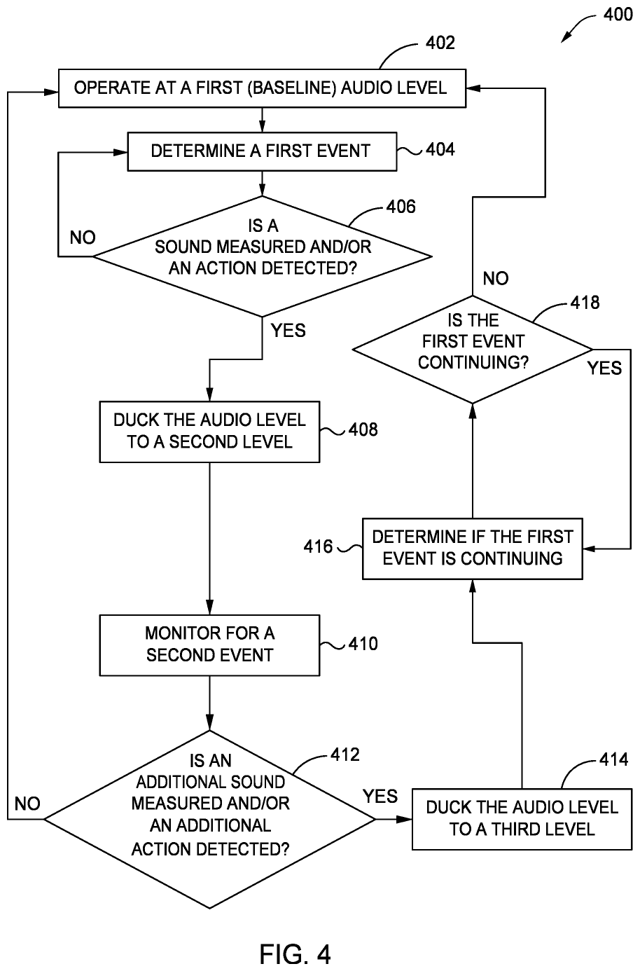

FIG. 4 is a state diagram illustrating example operations 400 performed by a wearable device (e.g., wearable device 110) for managing ambient noise using multi-stage actions, according to certain aspects of the present disclosure. The operations 400 may be similar to the operations 300 described with respect to FIG. 3.

The operations 400 begin at state 402, where the wearable device may operate at a first (baseline) audio level. As described above, the first audio level may be configurable by the user through the user input interface (e.g., user input interface 216, 217), and may include an audio volume level, a noise cancellation level, and a transparency level, or any other levels associated with the audio output of the wearable device. For example, the user may begin listening to audio output from the wearable device, and may set the first audio level based on the user's preference (e.g., by setting a desired audio volume level and noise cancellation level). When operating in state 402. the wearable device may proceed to state 404.

At state 404, the wearable device may determine a first event. As described above, determining the first event may involve at least one of measuring a user speech (e.g., self-voice), a non-speech vocalization (e.g., sneezing, crying, laughing), or an environmental sound (e.g., ambient noises and/or nearby voice), or detecting a user action (e.g., user turning their head or reacting in some manner to the event).

At state 406, the wearable device may determine when one or both of a sound has been measured by the one or more microphones, or an action has been detected by the one or more sensors (e.g., when the first event has been determined). When no sound has been measured and no action has been detected, the wearable device may return to state 404, and again determine a first event. When one or both of a sound has been measured and an action has been detected, the wearable device may proceed to state 408.

At state 408, the wearable device may duck the audio level to a second audio level. As described above, ducking the audio level of the wearable device may include at least one of decreasing an audio volume of the wearable device, decreasing a noise cancellation of the wearable device, increasing a transparency of the wearable device, pausing an audio output of the wearable device, or outputting a notification sound from the wearable device. In certain aspects, the wearable device may be configured to utilize gradual ducking to duck the audio level to a second audio level. After ducking the audio level, the wearable device may proceed to state 410.

At state 410, the wearable device may monitor for a second event. As described above, monitoring for the second event may involve at least one of measuring a sound using one or more microphones (e.g., microphones 111, 112) on the wearable device, or detecting an action using one or more sensors (e.g., body movement sensor) on the wearable device. The second event may involve at least one of a user speech (e.g., self-voice), a non-speech vocalization (e.g., sneezing, crying, laughing), an environmental sound (e.g., ambient noises and/or nearby voice), or a user action (e.g., user turning their head or reacting in some manner to the event), or a user action (e.g., user turning their head).

At state 412, the wearable device may determine when one or both of an additional sound has been measured by the one or more microphones, or an additional action has been detected by the one or more sensors (e.g., when the second event has been determined). When no additional sound has been measured and no action has been detected, the wearable device may return to state 410, and again monitor for the second event. When one or both of an additional sound has been measured and an additional action has been detected, the wearable device may proceed to state 414.

At state 414, the wearable device may duck the audio level to a third audio level. As described above, ducking the audio level of the wearable device may include at least one of decreasing an audio volume of the wearable device, decreasing a noise cancellation of the wearable device, increasing a transparency of the wearable device, pausing an audio output of the wearable device, or outputting a notification sound from the wearable device. In certain aspects, the wearable device may be configured to utilize gradual ducking to duck the audio level to the third audio level. After ducking the audio level, the wearable device may proceed to state 416.

At states 416, the wearable device may determine when the first event is continuing. As described above, determining if the first event is continuing may involve at least one of measuring a sound using one or more microphones on the wearable device, or detecting an action using one or more sensors on the wearable device.

At state 418, when the event is not continuing, operations 400 may proceed back to state 402, as described above, and the audio level may return to the first audio level. When the event is continuing, operations 400 may return to state 416. For example, when the wearable device has not measured any sound or detected any action, it may determine that the first event is not continuing, and infer that the user wishes to return their full attention to the audio output of the wearable device at the previous audio level before the interruption. In certain aspects, the wearable device may have a baseline period of time to determine if the first event is continuing, or may instead use a period of time set by the user. The period of time may be long enough to allow typical/normal pauses in conversation or other sound events (e.g., periods of time when there is no ambient noise) to pass without the wearable device triggering the return to the first audio level (isolating the user before the important event has ended). The period of time may also be short enough to minimize time that the user will wait for the return of the wearable device to the first audio level after the end of the important event (reducing the time before the return to the user's optimal audio experience). In certain aspects, returning the audio level of the wearable device to the first level may utilize gradual ducking, or abrupt or sudden ducking, as described above.

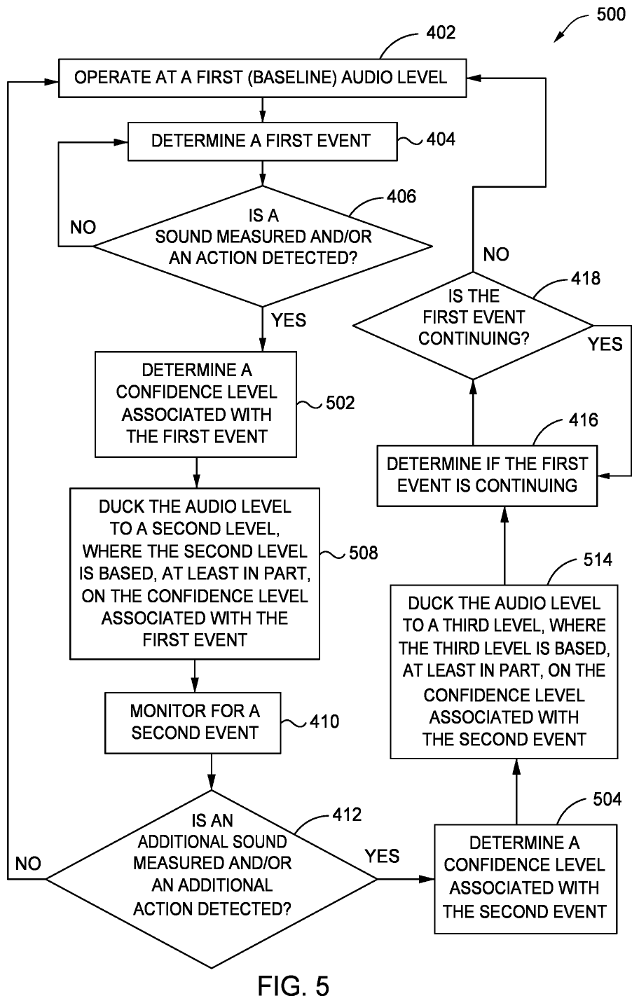

FIG. 5 is a state diagram illustrating example operations 500 performed by a wearable device (e.g., wearable device 110) for managing ambient noise using confidence-based actions, according to certain aspects of the present disclosure. The operations 500 may be similar to the operations 400 described with respect to FIG. 4.

At state 406, which is described above, the wearable device may determine when one or both of a sound has been measured by the one or more microphones, or an action has been detected by the one or more sensors. When one or both of a sound has been measured and an action has been detected, the wearable device may proceed to state 502.

At state 502, the wearable device may determine a confidence level associated with the first event. As described above, the confidence level determined by the wearable device may be based, at least in part, on one or more of the type of event that has been detected (e.g., self-voice, nearby voices, other ambient sounds), user programming (e.g., a user may program a confidence level associated with an event), or a user profile (e.g., based on past user activity and using artificial intelligence/machine learning).

At state 508, the wearable device may duck the audio level to a second level, where the second level is based, at least in part, on the confidence level associated with the first event. As described above, when the wearable device has a low confidence that the first event is an important event, the second audio level may be only slightly different from the first audio level, and when the wearable device has a high confidence that the first event is an important event, the second audio level may be very different than the first audio level. In certain aspects, the wearable device may be configured to utilize gradual ducking to duck the audio level to a second audio level, as described above. After ducking the audio level, the wearable device may proceed to state 410.

At state 410, which is described above, the wearable device may determine when one or both of an additional sound has been measured by the one or more microphones, or an additional action has been detected by the one or more sensors. When one or both of an additional sound has been measured and an additional action has been detected, the wearable device may proceed to state 504.

At state 504, the wearable device may determine a confidence level associated with the second event. Determining the confidence level associated with the second event may be similar to determining the confidence level associated with the first event, as described above. Also as described above, the confidence level associated with the monitored second event may be an updated version of the confidence level associated with the determined first event, based, at least in part, on one or more of the type of second event that has been detected, the user programming, or the user profile.

At state 514, the wearable device may duck the audio level to a third level, where the third level is based, at least in part, on the confidence level associated with the second event. In some cases, the confidence level associated with the monitored second event may be an updated version of the confidence level associated with the determined first event, based, at least in part, on one or more of the type of second event that has been detected, the user programming, or the user profile. As described above, the confidence level associated with the second event determined by the wearable device may be based, at least in part, on one or more of the type of event that has been detected (e.g., self-voice, nearby voices, other ambient sounds), user programming (e.g., a user may program a confidence level associated with an event), or a user profile (e.g., based on past user activity and using artificial intelligence/machine learning).

Although the operations 300, 400, 500 of FIGS. 3-5 are described with only two stages (ducking the audio level from the first level to the second level, and ducking the audio level from the second level to the third level), any number of stages may be used to manage ambient noise and facilitate user awareness and interaction.

It is noted that the processing related to ambient noise management as discussed in aspects of the present disclosure may be performed natively in the wearable device, by the computing device, or a combination thereof.

### Additional Considerations

It is noted that, descriptions of aspects of the present disclosure are presented above for purposes of illustration, but aspects of the present disclosure are not intended to be limited to any of the disclosed aspects. Many modifications and variations will be apparent to those of ordinary skill in the art without departing from the scope and spirit of the described aspects.

In the preceding, reference is made to aspects presented in this disclosure. However, the scope of the present disclosure is not limited to specific described aspects. Aspects of the present disclosure can take the form of an entirely hardware aspect, an entirely software aspect (including firmware, resident software, micro-code, etc.) or an aspect combining software and hardware aspects that can all generally be referred to herein as a “component,” “circuit,” “module” or “system.” Furthermore, aspects of the present disclosure can take the form of a computer program product embodied in one or more computer readable medium(s) having computer readable program code embodied thereon.

Any combination of one or more computer readable medium(s) can be utilized. The computer readable medium can be a computer readable signal medium or a computer readable storage medium. A computer readable storage medium can be, for example, but not limited to, an electronic, magnetic, optical, electromagnetic, infrared, or semiconductor system, apparatus, or device, or any suitable combination of the foregoing. More specific examples of a computer readable storage medium include: an electrical connection having one or more wires, a hard disk, a random access memory (RAM), a read-only memory (ROM), an erasable programmable read-only memory (EPROM or Flash memory), an optical fiber, a portable compact disc read-only memory (CD-ROM), an optical storage device, a magnetic storage device, or any suitable combination of the foregoing. In the current context, a computer readable storage medium can be any tangible medium that can contain, or store a program.

The flowchart and block diagrams in the Figures illustrate the architecture, functionality and operation of possible implementations of systems, methods and computer program products according to various aspects. In this regard, each block in the flowchart or block diagrams can represent a module, segment or portion of code, which comprises one or more executable instructions for implementing the specified logical function(s). In some alternative implementations the functions noted in the block can occur out of the order noted in the figures. For example, two blocks shown in succession can, in fact, be executed substantially concurrently, or the blocks can sometimes be executed in the reverse order, depending upon the functionality involved. Each block of the block diagrams and/or flowchart illustrations, and combinations of blocks in the block diagrams and/or flowchart illustrations can be implemented by special-purpose hardware-based systems that perform the specified functions or acts, or combinations of special purpose hardware and computer instructions.

What is claimed is:

1. A method for managing ambient noise in a wearable device, the method comprising:
determining a first event;
ducking an audio level of the wearable device from a first level to a second level based on the determination;
monitoring for a second event; and
ducking the audio level of the wearable device to a third level based on the monitoring, wherein the second level is different than the third level.

2. The method of claim 1, wherein ducking the audio level of the wearable device comprises gradually ducking the audio level of the wearable device.

3. The method of claim 1, wherein ducking the audio level of the wearable device comprises at least one of:
decreasing an audio volume of the wearable device;
decreasing a noise cancellation of the wearable device;
increasing a transparency of the wearable device;
pausing an audio output of the wearable device; or
outputting a notification sound from the wearable device.

4. The method of claim 1, wherein at least one of the second level or the third level is based, at least in part, on a user input.

5. The method of claim 1, further comprising determining a first confidence level associated with the first event, wherein the second level is based, at least in part, on the first confidence level.

6. The method of claim 5, wherein a duration of the ducking the audio level of the wearable device from the first level to the second level is based, at least in part, on the first confidence level.

7. The method of claim 5, further comprising determining a second confidence level associated with the second event, wherein the third level is based, at least in part, on the second confidence level.

8. The method of claim 5, wherein the first confidence level is based, at least in part, on one or more of:
a type of the first event;
a user input; or
a user profile.

9. The method of claim 1, wherein the first event and the second event each comprise at least one of:
a user speech vocalization;
a non-speech vocalization;
an environmental sound; or
a user action.

10. The method of claim 1, wherein determining the first event and monitoring for the second event each comprise:
measuring a sound using one or more microphones on the wearable device; or
detecting an action using one or more sensors on the wearable device.

11. The method of claim 1, further comprising:
determining that the first event is not continuing; and
returning the audio level of the wearable device to the first level based on the determination that the first event is not continuing.

12. A system, comprising:
a wearable device including one or more microphones configured to measure ambient sound; and
one or more processors coupled to the wearable device, the one or more processors configured to:
determine a first event;
duck an audio level of the wearable device from a first level to a second level based on the determination;
monitor for a second event; and
duck the audio level of the wearable device to a third level based on the monitoring, wherein the second level is different than the third level.

13. The system of claim 12, wherein the one or more processors are configured to duck the audio level of the wearable device by gradually ducking the audio level of the wearable device.

14. The system of claim 12, wherein to duck the audio level of the wearable device, the one or more processors are configured to at least one of:
decrease an audio volume of the wearable device;
decrease a noise cancellation of the wearable device;
increase a transparency of the wearable device;
pause an audio output of the wearable device; or
output a notification sound from the wearable device.

15. The system of claim 12, wherein the one or more processors are further configured to determine a first confidence level associated with the first event, wherein the second level is based, at least in part, on the first confidence level.

16. The system of claim 15, wherein the first confidence level is based, at least in part, on one or more of:
a type of the first event;
a user input; or a user profile.

17. A non-transitory computer-readable medium comprising computer-executable instructions that, when executed by one or more processors of a wearable device, cause the wearable device to perform a method for managing ambient noise, the method comprising:
determining a first event;
ducking an audio level of the wearable device from a first level to a second level based on the determination;
monitoring for a second event; and
ducking the audio level of the wearable device to a third level based on the monitoring, wherein the second level is different than the third level.

18. The non-transitory computer-readable medium of claim 17, wherein ducking the audio level of the wearable device comprises gradually ducking the audio level of the wearable device.

19. The non-transitory computer-readable medium of claim 17, wherein ducking the audio level of the wearable device comprises at least one of:
decreasing an audio volume of the wearable device;
decreasing a noise cancellation of the wearable device;
increasing a transparency of the wearable device;
pausing an audio output of the wearable device; or
outputting a notification sound from the wearable device.

20. The non-transitory computer-readable medium of claim 17, wherein the method further comprises determining a first confidence level associated with the first event, wherein the second level is based, at least in part, on the first confidence level.
